(19) United States
(12) Patent Application Publication
(10) Pub. No.: US 2015/0332813 A1
(43) Pub. Date: Nov. 19, 2015

(54) SUPERCONDUCTING FILM UNIT AND METHOD FOR MANUFACTURING THE SAME

(71) Applicant: INDUSTRIAL TECHNOLOGY RESEARCH INSTITUTE, Hsinchu (TW)

(72) Inventors: Der-Chung YAN, Taoyuan (TW); Maw-Kuen WU, Taipei (TW); Chia-Hao HSU, Taipei (TW); Shih-Yun CHEN, Taipei (TW)

(21) Appl. No.: 14/713,850

(22) Filed: May 15, 2015

(30) Foreign Application Priority Data
May 16, 2014 (TW) 103117380
Apr. 8, 2015 (TW) 104111340

(51) Int. Cl. H01B 12/06; H01L 39/24; H01L 39/12; H01B 13/00; H01B 1/08

(52) U.S. Cl. CPC H01B 12/06; H01B 13/0036; H01B 1/08; H01L 39/126; H01L 39/2448; H01L 39/2422

(57) ABSTRACT

The disclosure relates to a superconducting film unit and a method for manufacturing the same. The superconducting film unit includes a substrate and a superconducting film. The lattice constant of the substrate is between 5.0 Å and 5.5 Å. The superconducting film is disposed on the substrate. The superconducting film includes YBa₂Cu₃O₇ and Y₂BaCuO₅. The Y₂BaCuO₅ is dispersed in the YBa₂Cu₃O₇.

### CROSS-REFERENCE TO RELATED APPLICATIONS

This non-provisional application claims priority under 35 U.S.C. §119(a) on Patent Application No(s). 103117380 filed in Taiwan, R.O.C. on May 16, 2014 and Patent Application No(s). 104111340 filed in Taiwan, R.O.C. on Apr. 8, 2015, the entire contents of which are hereby incorporated by reference.

### TECHNICAL FIELD

The disclosure relates to a superconducting film unit and a method for manufacturing the same.

### BACKGROUND

Superconducting generators have advantages of small volumes, light weights and high efficiencies. Therefore, superconducting generators can be utilized in the fields of power generation.

At present, the cost of high temperature superconducting wires is expensive. Further, the critical current density of the superconducting wires manufactured by the current processes still needs to be improved. Therefore, it is important to improve the critical current density of the superconducting wires in the utilization of high temperature superconducting wires.

In general, superconducting wires are utilized under a high magnetic field. The magnetic flux pass through the superconducting wires as vortexes. Since there are Lorentz forces between the applied current in the superconducting wires and the vortexes, the vortexes move because of the Lorentz forces, so that the efficiencies of the superconducting wires are decreased. That is to say, it is important to reduce the movement of the vortexes because of the Lorentz forces.

Moreover, forming crystallographic defects or non-superconducting phases in the superconductor of the superconducting wires have been developed for reducing or avoiding the movement of the vortexes because of the Lorentz force. In detail, the crystallographic defects or non-superconducting phases are served as pinning centers, so that the motion of the vortexes moving in the superconductor is restricted. Therefore, the efficiencies of the superconducting wires are improved by the pinning centers formed in the superconductors.

Ionic irradiation can be utilized to form defects in the superconductor of the superconducting wires. However, the ionic irradiation is an expensive method for forming the defects. Therefore, it is more feasible to form non-superconducting phase of nano-particles in the superconductor serving as the pinning centers for mass production. Accordingly, it is important to improve the process for manufacturing non-superconducting phase of nano-particles in the superconductor to improve the efficiency of the superconducting wires.

### SUMMARY

According to an embodiment of the disclosure, a superconducting film unit is provided. A lattice constant of the substrate is between 5.0 Å and 5.5 Å. The superconducting film is disposed on the substrate. The superconducting film comprises YBa₂Cu₃O₇ and Y₂BaCuO₅. Wherein, the Y₂BaCuO₅ is dispersed in the YBa₂Cu₃O₇.

According to an embodiment of the disclosure, a method for manufacturing a superconducting film unit is provided. The method comprises the following steps. A substrate is provided, a lattice constant of the substrate being between 5.0 Å and 5.5 Å. A target is provided, the target comprises YBa₂Cu₃O₇ and Y₂BaCuO₅. A deposition process is performed, so that the target forms the YBa₂Cu₃O₇ and the Y₂BaCuO₅ on the substrate simultaneously, wherein the Y₂BaCuO₅ is dispersed in the YBa₂Cu₃O₇.

### BRIEF DESCRIPTION OF THE DRAWINGS

The present disclosure will become more fully understood from the detailed description given hereinbelow, along with the accompanying drawings which are for illustration only, thus are not limitative of the present disclosure, and wherein:

FIG. 1 is a flow chart of a method for manufacturing a superconducting film unit according to an embodiment of the disclosure;

FIG. 2A is a schematic diagram of a superconducting film unit according to an embodiment of the disclosure;

FIG. 2B is a schematic diagram of a superconducting wire according to an embodiment of the disclosure;

FIG. 3 is a TEM analysis of the superconducting film in Example 1 of the disclosure;

FIG. 4 is a TEM analysis of the superconducting film in Comparative Example 1 of the disclosure;

FIG. 5 is a TEM analysis of the superconducting film in Comparative Example 3 of the disclosure; and

FIG. 6 is a diagram of the critical current density of the superconducting films in Example 1 and 2, Comparative Example 1 and 2 under 77 K and different magnetic fields.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

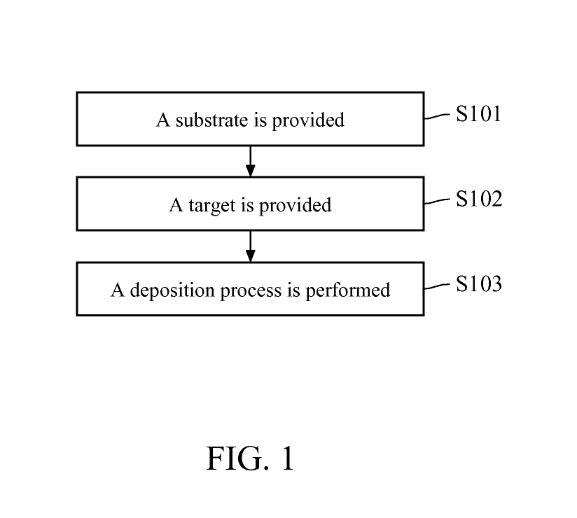

First, please refer to FIG. 1, which is a flow chart of a method for manufacturing a superconducting film unit according to an embodiment of the disclosure. First, a substrate is provided (S101). A lattice constant of the substrate is between 5.0 Å and 5.5 Å. The material of the substrate is, for example, Yttria-stabilized zirconia (YSZ, and the lattice constant of YSZ is 5.139 Å), lanthanum aluminate (LaAlO₃, LAO, and the lattice constant of LAO is 5.364 Å), Y₃NbO₇ (the lattice constant of Y₃NbO₇ is 5.250 Å), Gd₂Zr₂O₇ (the lattice constant of Gd₂Zr₂O₇ is 5.264 Å), CeO₂ (the lattice constant of CeO₂ is 5.411 Å) or NdGaO₃ (the lattice constant of NdGaO₃ is 5.431 Å). The disclosure is not limited thereto.

Then, a target is provided (S102). The target comprises yttrium, barium and copper. The constitutional elements of the target correspond to the superconducting film, which is going to be manufactured. In another embodiment of the disclosure, the target comprises, for example, YBa₂Cu₃O₇ and the Y₂BaCuO₅, and wherein a weight percentage of the Y₂BaCuO₅ is 5 wt % to 15 wt %, and the weight percentage of the Y₂BaCuO₅ is based on a total weight of the target. In some other embodiments, the weight percentage of the Y₂BaCuO₅ is 8 wt %, and the weight percentage of the Y₂BaCuO₅ is based on the total weight of the target. In this embodiment, the material of the manufactured superconducting film comprises YBa₂Cu₃O₇ (superconducting phase) and Y₂BaCuO₅ (non-superconducting phase), and a weight percentage of the Y₂BaCuO₅ is 5 wt % to 15 wt %, and the weight percentage of the Y₂BaCuO₅ is based on a total weight of the superconducting film. In some other embodiments, the weight percentage of the Y₂BaCuO₅ is 8 wt %, and the weight percentage of the Y₂BaCuO₅ is based on the total weight of the superconducting film. In this embodiment, the target is formed by, for example, a top seeded melt textured growth or a sintering process. Therefore, the target is more compact and has better quality, so that the critical current density (Jc) of the manufactured superconducting film is improved.

In this and other embodiments, the disclosure is not limited to the order of providing a substrate (S101) and providing a target (S102). In some other embodiments, a target is provided and then a substrate is provided.

Finally, a deposition process is performed (S103). Thereby, the target forms the YBa₂Cu₃O₇ and the Y₂BaCuO₅ on the substrate simultaneously. In this embodiment, the deposition process is a pulsed laser deposition, and a mean wavelength of a laser of the pulsed laser deposition is 248 nm. In this and some other embodiments, an energy density of the laser of the pulsed laser deposition is between 1.5 J/cm² and 2.0 J/cm². In this and some other embodiments, a temperature of the substrate during the deposition process is between 780° C. and 850° C.

During the deposition process, the target forms the YBa₂Cu₃O₇ and the Y₂BaCuO₅ respectively. Further, the YBa₂Cu₃O₇ and the Y₂BaCuO₅ contact the substrate, and the difference between the lattice constant of the substrate (5.0 Å to 5.5 Å) and the lattice constant of the superconducting-phase YBa₂Cu₃O₇ (a=3.821 Å, b=3.885 Å) is greater. Therefore, the YBa₂Cu₃O₇ and the Y₂BaCuO₅ are formed on the substrate simultaneously during the deposition process, while the Y₂BaCuO₅ is formed as nano-particles to be uniformly dispersed in the YBa₂Cu₃O₇. Thus, the miniaturization and the decentralization of the pinning centers are achieved.

When pinning centers are smaller and more decentralized, the quantity of pinning centers is increased, and the vortexes are distributed in the superconductor more uniformly. Thereby, the repulsive forces between the vortexes are lowered, and the effect of pinning is improved, which means the critical current density is elevated.

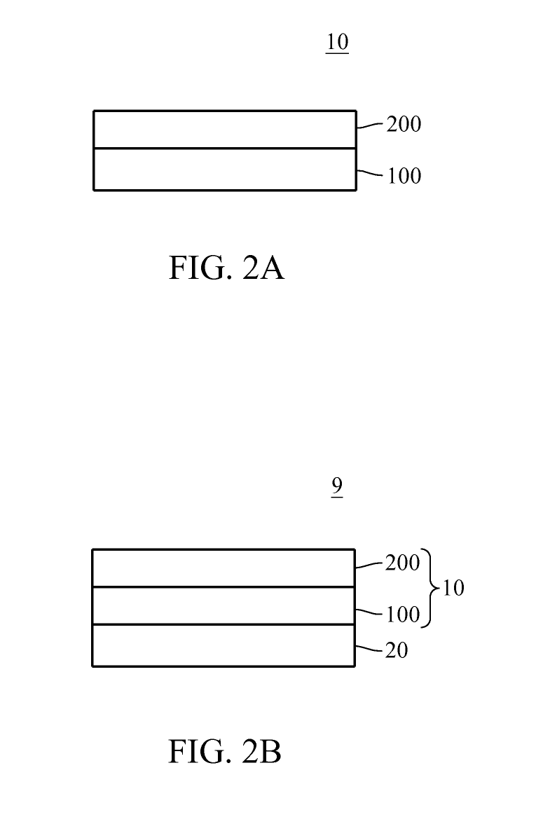

The followings describe the superconducting film unit of the disclosure. Please refer to FIG. 2A, which is a schematic diagram of a superconducting film unit according to an embodiment of the disclosure. The superconducting film unit 10 comprises a substrate 100 and a superconducting film 200. The substrate 100 described herein in the disclosure is considered as, for example, a buffer layer in a superconducting wire, more particularly, the substrate 100 is taken as the buffer layer where the superconducting film contact and is disposed. A lattice constant of the substrate 100 is between 5.0 Å and 5.5 Å. The superconducting film 200 is disposed on the substrate 100. The material of the superconducting film 200 comprises YBa₂Cu₃O₇ (superconducting phase) and Y₂BaCuO₅ (non-superconducting phase). The Y₂BaCuO₅ is dispersed in the YBa₂Cu₃O₇. Moreover, the YBa₂Cu₃O₇ and the Y₂BaCuO₅ contact the substrate 100.

In some other embodiments of the disclosure, the Y₂BaCuO₅ are nano-particles.

In some other embodiments of the disclosure, a diameter of the Y₂BaCuO₅ is between 15 nm and 30 nm.

In some other embodiments of the disclosure, a weight percentage of the Y₂BaCuO₅ is 5 wt % to 15 wt %, and the weight percentage of the Y₂BaCuO₅ is based on a total weight of the superconducting film 200. In some other embodiments of the disclosure, the weight percentage of the Y₂BaCuO₅ is 8 wt %, and the weight percentage of the Y₂BaCuO₅ is based on the total weight of the superconducting film 200.

In some other embodiments, the material of the substrate 100 is, Yttria-stabilized zirconia (YSZ, and the lattice constant of YSZ is 5.139 Å), lanthanum aluminate (LaAlO₃, LAO, and the lattice constant of LAO is 5.364 Å), Y₃NbO₇ (the lattice constant of Y₃NbO₇ is 5.250 Å), Gd₂Zr₂O₇ (the lattice constant of Gd₂Zr₂O₇ is 5.264 Å), CeO₂ (the lattice constant of CeO₂ is 5.411 Å) or NdGaO₃ (the lattice constant of NdGaO₃ is 5.431 Å). The disclosure is not limited thereto.

In some other embodiments, a thickness of the superconducting film 200 is between 150 nm and 350 nm.

The superconducting film unit 10 can be utilized on a superconducting wire. Please refer to FIG. 2B, which is a schematic diagram of a superconducting wire according to an embodiment of the disclosure. As shown in the figure, the superconducting wire 9 comprises a superconducting film unit 10 and a carrier 20. The superconducting film unit 10 is disposed on the carrier 20. Since the superconducting wire 9 comprises the superconducting film unit 10 of the disclosure, the performance of the superconducting wire 9 is improved.

The following Examples and Comparative Examples describe the method for manufacturing a superconducting film unit of the disclosure.

### EXAMPLE 1 (LAO)

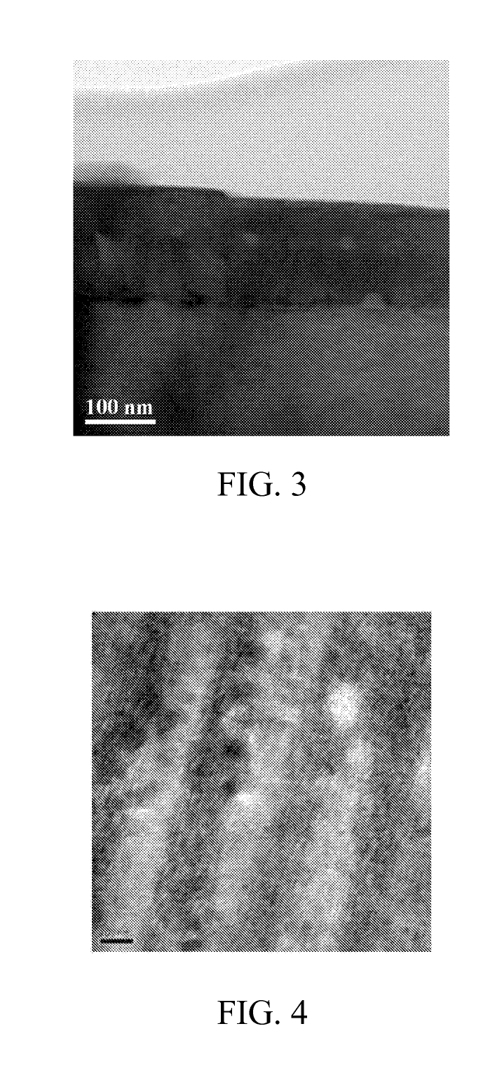

First, YBa₂Cu₃O₇ and Y₂BaCuO₅ powders are prepared as the starting materials. Y₂O₃, BaCO₃ and CuO powders are uniformly mixed in a mole ratio of 1:2:3 and 2:1:1, respectively. Then, the mixture is calcined under 900° C. for 8 hours. Afterwards, the mixture is grinded and then is calcined for 2 times. That is to say, the calcination process is performed 3 times. Thereby, the starting materials of YBa₂Cu₃O₇ and Y₂BaCuO₅ powders are obtained. Next, the starting materials of YBa₂Cu₃O₇ and Y₂BaCuO₅ powders are uniformly mixed in a mass ratio of 92:8. Then, the mixture is coalesced under a pressure of 25-35 MPa. Afterwards, a SmBa₂Cu₃O₇ crystal is placed on the center of a surface of the mixture to be served as a seed crystal. Then, the temperature is increased and maintained at 908° C. for 4 hours. Then, the temperature is elevated to 1045° C. and maintained for 1 hour. Afterwards, the temperature is cooled down from 1045° C. to 992° C. within a cooling rate of 4° C./hr. Then, the temperature is cooled down from 992° C. to 982° C. within a cooling rate of 0.2° C./hr. Finally, the temperature is cooled down to the room temperature, and the manufacture of the target is completed. The target of YBa₂Cu₃O₇ within 8 wt % of Y₂BaCuO₅ and the LAO substrate are disposed inside a chamber of a deposition device. Then, the pressure in the chamber is lowered to about 1×10⁻⁶ mbar by a pump. Next, the temperature of the substrate in the chamber is elevated to 850° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500 ° C. However, the disclosure is not limited to the thickness of the thin film. Then, 0.8-1 atmosphere (atm) of oxygen is introduced into the chamber and the pressure is maintained for 0.5-1 hr. Finally, the temperature is cooled down to the room temperature, and the manufacture of the superconducting film of Example 1 is completed. Please refer to FIG. 3, which is a TEM analysis of the superconducting film in Example 1 of the disclosure. As shown in FIG. 3, the Y₂BaCuO₅ is formed as particles to be uniformly dispersed in the YBa₂Cu₃O₇, and the diameter of the Y₂BaCuO₅ is between 15 nm and 30 nm.

### EXAMPLE 2 (YSZ)

First, YBa₂Cu₃O₇ and Y₂BaCuO₅ powders are prepared as the starting materials. Y₂O₃, BaCO₃ and CuO powders are uniformly mixed in a mole ratio of 1:2:3 and 2:1:1, respectively. Then, the mixture is calcined under 900° C. for 8 hours. Afterwards, the mixture is grinded and then is calcined for 2 times. That is to say, the calcination process is performed 3 times. Thereby, the starting materials of YBa₂Cu₃O₇ and Y₂BaCuO₅ powders are obtained. Next, the starting materials of YBa₂Cu₃O₇ and Y₂BaCuO₅ powders are uniformly mixed in a mass ratio of 92:8. Then, the mixture is coalesced under a pressure of 25-35 MPa. Afterwards, a SmBa₂Cu₃O₇ crystal is placed on the center of a surface of the mixture to be served as a seed crystal. Then, the temperature is increased and maintained at 908° C. for 4 hours. Then, the temperature is elevated to 1045° C. and maintained for 1 hour. Afterwards, the temperature is cooled down from 1045° C. to 992° C. within a cooling rate of 4° C./hr. Then, the temperature is cooled down from 992° C. to 982° C. within a cooling rate of 0.2° C./hr. Finally, the temperature is cooled down to the room temperature, and the manufacture of the target is completed. The target of YBa₂Cu₃O₇ within 8 wt % of Y₂BaCuO₅ and the YSZ substrate are disposed inside a chamber of a deposition device. Then, the pressure in the chamber is lowered to about 1×10⁻⁶ mbar by a pump. Next, the temperature of the substrate in the chamber is elevated to 850° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500° C. However, the disclosure is not limited to the thickness of the thin film. Then, 0.8-1 atm of oxygen is introduced into the chamber and the pressure is maintained for 0.5-1 hr. Finally, the temperature is cooled down to the room temperature, and the manufacture of the superconducting film of Example 2 is completed.

### EXAMPLE 3 (Y₃NbO₇)

First, YBa₂Cu₃O₇ and Y₂BaCuO₅ powders are prepared as the starting materials. Y₂O₃, BaCO₃ and CuO powders are uniformly mixed in a mole ratio of 1:2:3 and 2:1:1, respectively. Then, the mixture is calcined under 900° C. for 8 hours. Afterwards, the mixture is grinded and then is calcined for 2 times. That is to say, the calcination process is performed 3 times. Thereby, the starting materials of YBa₂Cu₃O₇ and Y₂BaCuO₅ powders are obtained. Next, the starting materials of YBa₂Cu₃O₇ and Y₂BaCuO₅ powders are uniformly mixed in a mass ratio of 92:8. Then, the mixture is coalesced under a pressure of 25-35 MPa. Afterwards, a SmBa₂Cu₃O₇ crystal is placed on the center of a surface of the mixture to be served as a seed crystal. Then, the temperature is increased and maintained at 908° C. for 4 hours. Then, the temperature is elevated to 1045° C. and maintained for 1 hour. Afterwards, the temperature is cooled down from 1045° C. to 992° C. within a cooling rate of 4° C./hr. Then, the temperature is cooled down from 992° C. to 982° C. within a cooling rate of 0.2° C./hr. Finally, the temperature is cooled down to the room temperature, and the manufacture of the target is completed. The target of YBa₂Cu₃O₇ within 8 wt % of Y₂BaCuO₅ and the Y₃NbO₇ substrate are disposed inside a chamber of a deposition device. Then, the pressure in the chamber is lowered to about 1×10⁻⁶ mbar by a pump. Next, the temperature of the substrate in the chamber is elevated to 850° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500° C. However, the disclosure is not limited to the thickness of the thin film. Then, 0.8-1 atm of oxygen is introduced into the chamber and the pressure is maintained for 0.5-1 hr. Finally, the temperature is cooled down to the room temperature, and the manufacture of the superconducting film of Example 3 is completed.

### EXAMPLE 4 (Gd₂Zr₂O₇)

First, YBa₂Cu₃O₇ and Y₂BaCuO₅ powders are prepared as the starting materials. Y₂O₃, BaCO₃ and CuO powders are uniformly mixed in a mole ratio of 1:2:3 and 2:1:1, respectively. Then, the mixture is calcined under 900° C. for 8 hours. Afterwards, the mixture is grinded and then is calcined for 2 times. That is to say, the calcination process is performed 3 times. Thereby, the starting materials of YBa₂Cu₃O₇ and Y₂BaCuO₅ powders are obtained. Next, the starting materials of YBa₂Cu₃O₇ and Y₂BaCuO₅ powders are uniformly mixed in a mass ratio of 92:8. Then, the mixture is coalesced under a pressure of 25-35 MPa. Afterwards, a SmBa₂Cu₃O₇ crystal is placed on the center of a surface of the mixture to be served as a seed crystal. Then, the temperature is increased and maintained at 908° C. for 4 hours. Then, the temperature is elevated to 1045° C. and is maintained for 1 hour. Afterwards, the temperature is cooled down from 1045° C. to 992° C. within a cooling rate of 4° C./hr. Then, the temperature is cooled down from 992° C. to 982° C. within a cooling rate of 0.2° C./hr. Finally, the temperature is cooled down to the room temperature, and the manufacture of the target is completed. The target of YBa₂Cu₃O₇ within 8 wt % of Y₂BaCuO₅ and the Gd₂Zr₂O₇ substrate are disposed inside a chamber of a deposition device. Then, the pressure in the chamber is lowered to about 1×10⁻⁶ mbar by a pump. Next, the temperature of the substrate in the chamber is elevated to 850° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500° C. However, the disclosure is not limited to the thickness of the thin film. Then, 0.8-1 atm of oxygen is introduced into the chamber and the pressure is maintained for 0.5-1 hr. Finally, the temperature is cooled down to the room temperature, and the manufacture of the superconducting film of Example 4 is completed.

### EXAMPLE 5 (CeO₂)

First, YBa₂Cu₃O₇ and Y₂BaCuO₅ powders are prepared as the starting materials. Y₂O₃, BaCO₃ and CuO powders are uniformly mixed in a mole ratio of 1:2:3 and 2:1:1, respectively. Then, the mixture is calcined under 900° C. for 8 hours. Afterwards, the mixture is grinded and then is calcined for 2 times. That is to say, the calcination is process is performed 3 times. Thereby, the starting materials of YBa₂Cu₃O₇ and Y₂BaCuO₅ powders are obtained. Next, the starting materials of YBa₂Cu₃O₇ and Y₂BaCuO₅ powders are uniformly mixed in a mass ratio of 92:8. Then, the mixture is coalesced under a pressure of 25-35 MPa. Afterwards, a SmBa₂Cu₃O₇ crystal is placed on the center of a surface of the mixture to be served as a seed crystal. Then, the temperature is increased and maintained at 908° C. for 4 hours. Then, the temperature is elevated to 1045° C. and maintained for 1 hour. Afterwards, the temperature is cooled down from 1045° C. to 992° C. within a cooling rate of 4° C./hr. Then, the temperature is cooled down from 992° C. to 982° C. within a cooling rate of 0.2° C./hr. Finally, the temperature is cooled down to the room temperature, and the manufacture of the target is completed. The target of YBa₂Cu₃O₇ within 8 wt % of Y₂BaCuO₅ and the CeO₂ substrate are disposed inside a chamber of a deposition device. Then, the pressure in the chamber is lowered to about 1×10⁻⁶ mbar by a pump. Next, the temperature of the substrate in the chamber is elevated to 850° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500° C. However, the disclosure is not limited to the thickness of the thin film. Then, 0.8-1 atm of oxygen is introduced into the chamber and the pressure is maintained for 0.5-1 hr. Finally, the temperature is cooled down to the room temperature, and the manufacture of the superconducting film of Example 5 is completed.

### EXAMPLE 6 (NdGaO₃)

First, YBa₂Cu₃O₇ and Y₂BaCuO₅ powders are prepared as the starting materials. Y₂O₃, BaCO₃ and CuO powders are uniformly mixed in a mole ratio of 1:2:3 and 2:1:1, respectively. Then, the mixture is calcined under 900° C. for 8 hours. Afterwards, the mixture is grinded and then is calcined for 2 times. That is to say, the calcination process is performed 3 times. Thereby, the starting materials of YBa₂Cu₃O₇ and Y₂BaCuO₅ powders are obtained. Next, the starting materials of YBa₂Cu₃O₇ and Y₂BaCuO₅ powders are uniformly mixed in a mass ratio of 92:8. Then, the mixture is coalesced under a pressure of 25-35 MPa. Afterwards, a SmBa₂Cu₃O₇ crystal is placed on the center of a surface of the mixture to be served as a seed crystal. Then, the temperature is increased and maintained at 908° C. for 4 hours. Then, the temperature is elevated to 1045° C. and maintained for 1 hour. Afterwards, the temperature is cooled down from 1045° C. to 992° C. within a cooling rate of 4° C./hr. Then, the temperature is cooled down from 992° C. to 982° C. within a cooling rate of 0.2° C./hr. Finally, the temperature is cooled down to the room temperature, and the manufacture of the target is completed. The target of YBa₂Cu₃O₇ within 8 wt % of Y₂BaCuO₅ and the NdGaO₃ substrate are disposed inside a chamber of a deposition device. Then, the pressure in the chamber is lowered to about 1×10⁻⁶ mbar by a pump. Next, the temperature of the substrate in the chamber is elevated to 850° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500° C. However, the disclosure is not limited to the thickness of the thin film. Then, 0.8-1 atm of oxygen is introduced into the chamber and the pressure is maintained for 0.5-1 hr. Finally, the temperature is cooled down to the room temperature, and the manufacture of the superconducting film of Example 6 is completed.

### COMPARATIVE EXAMPLE 1 (STO)

First, YBa₂Cu₃O₇ and Y₂BaCuO₅ powders are prepared as the starting materials. Y₂O₃, BaCO₃ and CuO powders are uniformly mixed in a mole ratio of 1:2:3 and 2:1:1, respectively. Then, the mixture is calcined under 900° C. for 8 hours. Afterwards, the mixture is grinded and then is calcined for 2 times. That is to say, the calcination process is performed 3 times. Thereby, the starting materials of YBa₂Cu₃O₇ and Y₂BaCuO₅ powders are obtained. Next, the starting materials of YBa₂Cu₃O₇ and Y₂BaCuO₅ powders are uniformly mixed in a mass ratio of 92:8. Then, the mixture is coalesced under a pressure of 25-35 MPa. Afterwards, a SmBa₂Cu₃O₇ crystal is placed on the center of a surface of the mixture to be served as a seed crystal. Then, the temperature is increased and maintained at 908° C. for 4 hours. Then, the temperature is elevated to 1045° C. and maintained for 1 hour. Afterwards, the temperature is cooled down from 1045° C. to 992° C. within a cooling rate of 4° C./hr. Then, the temperature is cooled down from 992° C. to 982° C. within a cooling rate Of 0.2° C./hr. Finally, the temperature is cooled down to the room temperature, and the manufacture of the target is completed. The target of YBa₂Cu₃O₇ within 8 wt % of Y₂BaCuO₅ and the STO (SrTiO₃) substrate are disposed inside a chamber of a deposition device. Then, the pressure in the chamber is lowered to about 1×10⁻⁶ mbar by a pump. Next, the temperature of the substrate in the chamber is elevated to 850° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500° C. However, the disclosure is not limited to the thickness of the thin film. Then, 0.8-1 atm of oxygen is introduced into the chamber and the pressure is maintained for 0.5-1 hr. Finally, the temperature is cooled down to the room temperature, and the manufacture of the superconducting film of Comparative Example 1 is completed. Please refer to FIG. 4, which is a TEM analysis of the superconducting film in Comparative Example 1 of the disclosure. As shown in the figure, the black section represents the YBa₂Cu₃O₇, and the white section represents the Y₂BaCuO₅. The Y₂BaCuO₅ in the superconducting film in Comparative Example 1 aggregates as layers.

### COMPARATIVE EXAMPLE 2 (STO)

First, YBa₂Cu₃O₇ powders are prepared as the starting materials. Y₂O₃, BaCO₃ and CuO powders are uniformly mixed in a mole ratio of 1:2:3. Then, the mixture is calcined Under 900° C. for 8 hours. Afterwards, the mixture is grinded and then is calcined for 2 times. That is to say, the calcination process is performed 3 times. Thereby, the starting materials of YBa₂Cu₃O₇ powders are obtained. Next, the mixture is coalesced under a pressure of 25-35 MPa. Afterwards, the mixture is sintered under 900° C. for 8 hours. Finally, the temperature is cooled down to the room temperature, and the manufacture of the target of YBa₂Cu₃O₇ is completed. The target of YBa₂Cu₃O₇ and the STO (SrTiO₃) substrate are disposed inside a chamber of a deposition device. Then, the pressure in the chamber is lowered to about 1×10⁻⁶ mbar by a pump. Next, the temperature of the substrate in the chamber is elevated to 780° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500° C. Then, 0.8-1 atm of oxygen is introduced into the chamber and the pressure is maintained for 0.5-1 hr. Finally, the temperature is cooled down to the room temperature, and the manufacture of the superconducting film of Comparative Example 2 is completed.

### COMPARATIVE EXAMPLE 3 (MgO)

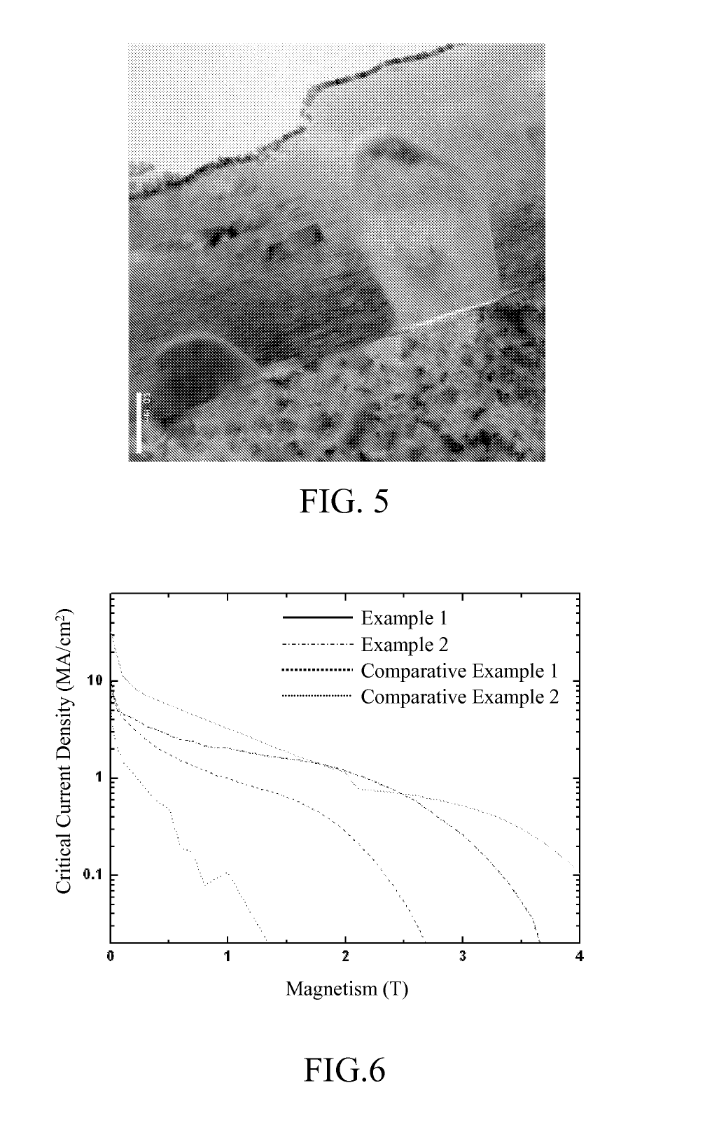

First, YBa₂Cu₃O₇ and Y₂BaCuO₅ powders are prepared as the starting materials. Y₂O₃, BaCO₃ and CuO powders are uniformly mixed in a mole ratio of 1:2:3 and 2:1:1, respectively. Then, the mixture is calcined under 900° C. for 8 hours. Afterwards, the mixture is grinded and then is calcined for 2 times. That is to say, the calcination process is performed 3 times. Thereby, the starting materials of YBa₂Cu₃O₇ and Y₂BaCuO₅ powders are obtained. Next, the starting materials of YBa₂Cu₃O₇ and Y₂BaCuO₅ powders are uniformly mixed in a mass ratio of 92:8. Then, the mixture is coalesced under a pressure of 25-35 MPa. Afterwards, a SmBa₂Cu₃O₇ crystal is placed on the center of a surface of the mixture to be served as a seed crystal. Then, the temperature is increased and maintained at 908° C. for 4 hours. Then, the temperature is elevated to 1045° C. and maintained for 1 hour. Afterwards, the temperature is cooled down from 1045° C. to 992° C. within a cooling rate of 4° C./hr. Then, the temperature is cooled down from 992° C. to 982° C. within a cooling rate of 0.2° C./hr. Finally, the temperature is cooled down to the room temperature, and the manufacture of the target is completed. The target of YBa₂Cu₃O₇ within 8 wt % of Y₂BaCuO₅ and the MgO substrate are disposed inside a chamber of a deposition device. Then, the pressure in the chamber is lowered to about 1×10⁻⁶ mbar by a pump. Next, the temperature of the substrate in the chamber is elevated to 850° C. Then, 300 mTorr of oxygen is introduced into the chamber. Afterwards, a deposition process is performed by a laser source having a mean wavelength of 248 nm. Thereby, the target is deposited onto the substrate, so that a thin film is formed on the substrate. The energy density of the laser is between 1.5 J/cm² and 2.0 J/cm². After the thickness of the thin film (i.e. the superconducting film) is accumulated to be between 150 and 350 nm, the temperature of the substrate in the chamber is cooled down to 500° C. Then, 0.8-1 atm of oxygen is introduced into the chamber and the pressure is maintained for 0.5-1 hr. Finally, the temperature is cooled down to the room temperature, and the manufacture of the superconducting film of Comparative Example 3 is completed. Please refer to FIG. 5, which is a TEM analysis of the superconducting film in Comparative Example 3 of the disclosure. As shown in FIG. 5, the magnesium of the substrate diffuses to the superconducting film.

Please refer to Tables 1-2. Table 1 shows the comparison of the substrates, the lattice constants, the targets and the critical current densities of the superconducting films between Examples 1-2. Table 2 shows the comparison of the substrates, the lattice constants, the targets and the critical current densities of the superconducting films between Comparative Examples 1-3. The targets in Examples 1-2, Comparative Example 1 and Comparative Example 3 are identical (YBa₂Cu₃O₇ and Y₂BaCuO₅) while the substrates in Examples 1-2, Comparative Example 1 and Comparative Example 3 are different. In

Comparative Example 2, the target is YBa₂Cu₃O₇.

TABLE 1

| | Example 1 | Example 2 |
|---|---|---|
| Substrate | LAO | YSZ |
| Lattice constant of | 5.364 Å | 5.139 Å |
| substrate | | |
| Target | YBa₂Cu₃O₇/Y₂BaCuO₅ | YBa₂Cu₃O₇/Y₂BaCuO₅ |
| Critical current | 3.26 MA/cm² | 2.06 MA/cm² |
| density | | |
| (77K, 1 Tesla) | | |

TABLE 2

| | Comparative | Comparative | Comparative |
|---|---|---|---|
| | Example 1 | Example 2 | Example 3 |
| Substrate | STO | STO | MgO |
| Lattice constant of | 3.905 Å | 3.905 Å | 4.212 Å |
| substrate | | | |
| Target | YBa₂Cu₃O₇/ | YBa₂Cu₃O₇ | YBa₂Cu₃O₇/ |
| | Y₂BaCuO₅ | | Y₂BaCuO₅ |
| Critical current density | 0.99 MA/cm² | 0.11 MA/cm² | none |
| (77K, 1 Tesla) | | | |

Since the difference between the lattice constants of the substrates in Examples 1-2 and the lattice constant of the YBa₂Cu₃O₇ (a=3.821A, b=3.885A) is greater, the YBa₂Cu₃O₇ and the Y₂BaCuO₅ are formed on the substrate simultaneously during the deposition process, while the Y₂BaCuO₅ is formed as nano-particles to be uniformly dispersed in the YBa₂Cu₃O₇. Thus, the miniaturization and the decentralization of the pinning centers are achieved. The above result can be realized in the TEM analysis of FIG. 3. With regard to Comparative Example 1, the difference between Comparative Example 1 and Examples 1-2 is that the substrate used in Comparative Example 1 is STO, which has a lattice constant of 3.905 A and is closed to the lattice constant of the YBa₂Cu₃O₇ in the superconducting films. In the TEM analysis of FIG. 4, the black area represents the YBa₂Cu₃O₇, and the white area represents the Y₂BaCuO₅. Compared with FIG. 3, in the TEM analysis of FIG. 4, the difference between the lattice constant of the STO substrate used in Comparative Example 1 and the lattice constant of the YBa₂Cu₃O₇ in the superconducting film is smaller, so that the Y₂BaCuO₅ aggregates as layers, rather than formed as nano-particles to be dispersed in the YBa₂Cu₃O₇ shown in FIG. 3. In other words, when pinning centers are smaller and more decentralized, the quantity of pinning centers is increased, and the vortexes are distributed in the superconductor more evenly.

Thereby, the repulsive forces between the vortexes are lowered, and the effect of pinning is improved, which means the critical current density is elevated. As shown in Table 1, the critical current density of Example 1 (3.26 MA/cm²) and the critical current density of Example 2 (2.06 MA/cm²) are significantly greater than the current density of Comparative Example 1 (0.99 MA/cm²).

In Comparative Example 2, since the target in Comparative Example 2 does not have Y₂BaCuO₅, the critical current density in Comparative Example 2 is significantly smaller (0.11 MA/cm²).

Regarding Comparative Example 3, since the substrate temperature during the deposition process is between 780 ° C. and 850 ° C., magnesium in the MgO substrate diffuses to the superconducting film during the deposition process. As shown in FIG. 5, magnesium diffuses to the superconducting film, so that the superconductivity of the superconducting phase in the superconducting film is deteriorated. Please refer to FIG. 6, which is a diagram of the critical current density of the superconducting films in Example 1 and 2, Comparative Example 1 and 2 under 77 K and different magnetic fields. As shown in the figure, the critical current density (Jc) of the superconducting film in Example 1 is 3.26 MA/cm² under 77K and 1T, and the critical current density (Jc) of the superconducting film in Example 2 is 2.06 MA/cm² under 77K and 1T. However, under the same conditions, the critical current density of the superconducting films in Comparative Example 1 and Comparative Example 2 are 0.99 MA/cm² and 0.11 MA/cm², respectively.

According to the superconducting film unit and the method for manufacturing the same of the disclosure, the superconducting film is deposited on the substrate by the single target. The target forms YBa₂Cu₃O₇ (superconducting phase) and the Y₂BaCuO₅ (non-superconducting phase) on the substrate. Also, the lattice constant of the substrate is between 5.0 Å to 5.5 Å, so that the difference between the lattice constant of the substrate and the lattice constant of the superconducting film is greater. Therefore, the Y₂BaCuO₅ is formed as particles to be uniformly dispersed in the YBa₂Cu₃O₇. The miniaturization and the decentralization of the pinning centers are achieved, such that the quantity of pinning centers is increased, and the vortexes are distributed in the superconductor more uniformly.

As a result, the repulsive forces between the vortexes are lowered, and the effect of pinning is improved, which means the critical current density is elevated.

In some other embodiments of the disclosure, the target is formed by a top seeded melt textured growth or a sintering process. Therefore, the target is more compact, so that the quality of the manufactured superconducting film is improved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A superconducting film unit, comprising:
a substrate, a lattice constant of the substrate being between 5.0 Å and 5.5 Å; and
a superconducting film, disposed on the substrate, the superconducting film comprising YBa₂Cu₃O₇ and Y₂BaCuO₅;
wherein, the Y₂BaCuO₅ is dispersed in the YBa₂Cu₃O₇.

2. The superconducting film unit according to claim 1, wherein the Y₂BaCuO₅ and the YBa₂Cu₃O₇ contact the substrate.

3. The superconducting film unit according to claim 1, wherein a weight percentage of the Y₂BaCuO₅ is 5 wt % to 15 wt %, and the weight percentage of the Y₂BaCuO₅ is based on a total weight of the superconducting film.

4. The superconducting film unit according to claim 1, wherein the substrate is Yttria-stabilized zirconia (YSZ), lanthanum aluminate (LAO), Y₃NbO₇, Gd₂Zr₂O₇, CeO₂ or NdGaO₃.

5. The superconducting film unit according to claim 1, wherein the Y₂BaCuO₅ is formed as particles to be dispersed in the YBa₂Cu₃O₇.

6. The superconducting film unit according to claim 5, wherein a diameter of the Y₂BaCuO₅ is between 15 nm and 30 nm.

7. The superconducting film unit according to claim 1, wherein a thickness of the superconducting film is between 150 nm and 350 nm.

8. The superconducting film unit according to claim 1, wherein the superconducting film unit is utilized in a superconducting wire.

9. A method for manufacturing a superconducting film unit, comprising:
providing a substrate, a lattice constant of the substrate being between 5.0 Å and 5.5 Å;
providing a target, the target comprising YBa₂Cu₃O₇ and Y₂BaCuO₅; and
performing a deposition process, the target forming the YBa₂Cu₃O₇ and the Y₂BaCuO₅ on the substrate simultaneously, wherein the Y₂BaCuO₅ is dispersed in the YBa₂Cu₃O₇.

10. The method according to claim 9, wherein a temperature of the substrate during the deposition process is between 780° C. and 850° C.

11. The method according to claim 9, wherein the deposition process is a pulsed laser deposition.

12. The method according to claim 11, wherein an energy density of a laser of the pulsed laser deposition is between 1.5 J/cm² and 2.0 J/cm².

13. The method according to claim 11, wherein a mean wavelength of a laser of the pulsed laser deposition is 248 nm.

14. The method according to claim 9, before the deposition process, further comprising:
performing a top seeded melt textured growth process or a sintering process.

15. The method according to claim 9, wherein a weight percentage of the Y₂BaCuO₅ is 5 wt % to 15 wt %, and the weight percentage of the Y₂BaCuO₅ is based on a total weight of the target.

16. The method according to claim 9, wherein the Y₂BaCuO₅ is formed as particles to be dispersed in the YBa₂Cu₃O₇ during the deposition process.

17. The method according to claim 9, wherein the substrate is Yttria-stabilized zirconia (YSZ), lanthanum aluminate (LAO), Y₃NbO₇, Gd₂Zr₂O₇, CeO₂ or NdGaO₃.

18. The method according to claim 9, wherein the Y₂BaCuO₅ and the YBa₂Cu₃O₇ contact the substrate.
